(19) United States
(12) Patent Application Publication
(10) Pub. No.: US 2018/0135179 A1
(43) Pub. Date: May 17, 2018

(54) Gas Injector and Vertical Heat Treatment Apparatus

(71) Applicant: TOKYO ELECTRON LIMITED, Tokyo (JP)

(72) Inventors: Toshiyuki IKEUCHI, Nirasaki City (JP); Hiromi SHIMA, Nirasaki City (JP); Keisuke SUZUKI, Nirasaki City (JP)

(21) Appl. No.: 15/810,768

(22) Filed: Nov. 13, 2017

(30) Foreign Application Priority Data
Nov. 14, 2016 (JP) 2016-221523

(51) Int. Cl. C23C 16/46; C23C 16/455; C23C 16/44; H01L 21/02

(52) U.S. Cl. CPC C23C 16/46; C23C 16/45527; C23C 16/45544; H01L 21/0217; C23C 16/4412; H01L 21/0228; H01L 21/02164; C23C 16/45578

(57) ABSTRACT

A gas injector is installed in a vertical heat treatment apparatus which performs a heat treatment on substrates held by a substrate holder and is loaded into a vertical reaction container around which a heating part is disposed. The gas injector supplies a film forming gas to the substrates into the reaction container. The gas injector includes: a tubular injector main body disposed inside the reaction container so as to extend in a vertical direction and has gas supply holes formed therein along the vertical direction; and a tubular gas introduction pipe installed to be integrated with the tubular injector main body in the vertical direction and includes a gas inlet to which the film forming gas is inputted and a gas introduction port which communicates with an internal space of the tubular injector main body and through which the film forming gas is introduced into the internal space.

### CROSS-REFERENCE TO RELATED APPLICATION

This application is based upon and claims the benefit of priority from Japanese Patent Application No. 2016-221523, filed on Nov. 14, 2016, the entire contents of which are incorporated herein by reference.

### TECHNICAL FIELD

The present disclosure relates to a technique for supplying a film forming gas into a vertical heat treatment apparatus to form a film on a substrate.

### BACKGROUND

In a process of manufacturing a semiconductor device, as a method of forming a film on a surface of a semiconductor wafer (hereinafter referred to as a “wafer”) as a substrate, an atomic layer deposition (ALD) method of forming a metal film on the surface of the wafer by alternately supplying a precursor gas containing a metal precursor and the like and a reaction gas reacting with the precursor gas, and a molecular layer deposition (MLD) method of forming a film of a compound containing metal are known. In the following description, the ALD method and the MLD method will be generally and simply referred to as an “ALD method”.

As one type of apparatus for carrying out the above-mentioned ALD method, a batch type vertical heat treatment apparatus is known which collectively performs a film forming process on a plurality of wafers received in a vertical reaction container. In such a vertical heat treatment apparatus, a substrate holder which holds a plurality of wafers vertically arranged in a shelf shape is loaded into the reaction container where the film forming process is performed.

As such, in a case where the vertical heat treatment apparatus is used, from the viewpoint of forming a film having a uniform wafer inter-plane film thickness distribution, a precursor gas and a reaction gas (hereinafter collectively referred to as a “film forming gas” in some cases) are required to be supplied onto the wafers held by the substrate holder as uniform as possible.

For example, there is a vertical heat treatment apparatus provided with a nozzle. The nozzle extends from an internal lower side of a process container to an internal upper side thereof and is bent in a U-shaped folded shape. A leading end of the nozzle extends to the internal lower side of the process container. In such a nozzle, a pressure of gas becomes higher toward the upstream side. Thus, a higher flow rate of gas is injected from gas injection holes formed at the upstream side. For this reason, the nozzle is folded in a U shape, and a flow rate distribution of gas supplied from a series of gas injection holes formed at the upstream side with respect to the folded portion of the nozzle and a flow rate distribution of gas supplied from a series of gas injection holes formed at the downstream side with respect to the folded portion are combined with each other so that the gas is uniformly supplied in the vertical direction when viewed from the whole nozzle.

On the other hand, the nozzle having a U-shaped folded shape tends to be increased in size, making it difficult for the nozzle to be arranged inside a process container of a predetermined size. In this case, it is not realistic to upsize the entire vertical heat treatment apparatus including the process container merely only for the purpose of arranging the nozzle.

In addition, there is known a nozzle having a double tube structure including an inner tube into which a purge gas is supplied and an outer tube into which a process gas is supplied. However, this technique is not intended to uniformly supply the process gas onto wafers held by a substrate holder.

### SUMMARY

Some embodiments of the present disclosure provide a gas injector capable of supplying a film forming gas suitable for a vertical heat treatment apparatus while limiting an increase in size of a nozzle, and a vertical heat treatment apparatus including the gas injector.

According to one embodiment of the present disclosure, there is provided a gas injector installed in a vertical heat treatment apparatus which performs a heat treatment on a plurality of substrates held by a substrate holder which holds the plurality of substrates vertically arranged in a shelf shape and is loaded into a vertical reaction container around which a heating part is disposed, the gas injector being configured to supply a film forming gas for film formation to the plurality of substrates into the vertical reaction container, including: a tubular injector main body disposed inside the vertical reaction container so as to extend in a vertical direction and has a plurality of gas supply holes formed therein along the vertical direction; and a tubular gas introduction pipe installed to be integrated with the tubular injector main body in the vertical direction and includes a gas inlet to which the film forming gas is inputted and a gas introduction port which communicates with an internal space of the tubular injector main body and through which the film forming gas is introduced into the internal space.

According to another embodiment of the present disclosure, there is provided a vertical heat treatment apparatus which includes the aforementioned gas injector.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional view of a vertical heat treatment apparatus including a gas injector according to an embodiment.

FIG. 2 is a longitudinal cross-sectional view of the gas injector.

FIG. 3 is an explanatory view of a conventional gas injector.

FIG. 4 is an explanatory view of a U-shaped folded gas injector.

FIGS. 5A to 5C are views used to explain how to change an internal pressure of the gas injector.

FIG. 6 is an explanatory view illustrating a modification of the gas injector.

FIGS. 7A and 7B are explanatory views illustrating another modification of the gas injector.

FIGS. 8A and 8B are explanatory views showing experimental results according to an Example and Comparative Example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

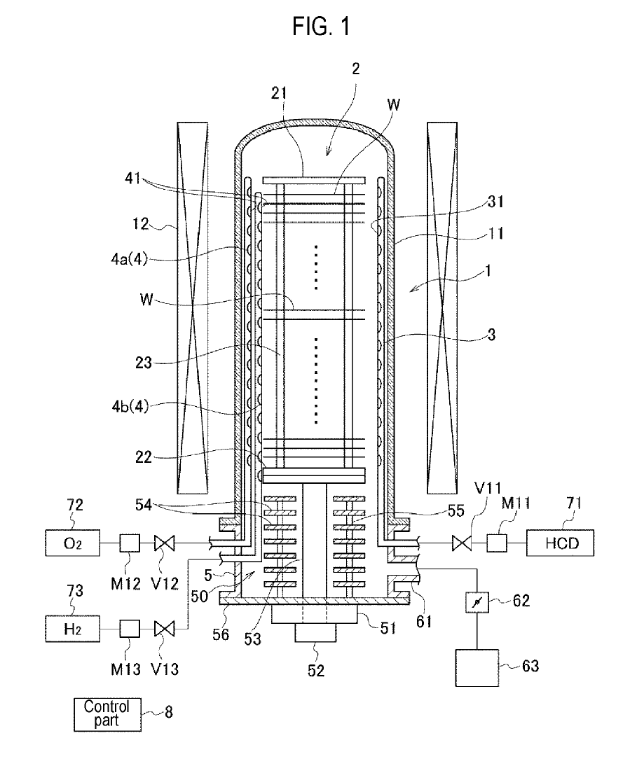

First, a configuration example of a vertical heat treatment apparatus having a number of gas supply holes 31 formed therein, according to an embodiment of the present disclosure, will be described with reference to FIG. 1. In this embodiment, the vertical heat treatment apparatus for forming an SiO₂ film on a wafer W using an ALD method by reacting a hexachlorodisilane (HCD) gas as a precursor gas with active species including O radicals and OH radicals as a reaction gas, will be described.

The vertical heat treatment apparatus includes a cylindrical reaction tube 11 made of quartz, with its upper end side closed and its lower end side opened. A manifold 5, which is formed of a stainless steel tubular member and is hermetically connected to the opening of the reaction tube 11, is installed below the reaction tube 11. A flange is formed at the lower end of the manifold 5. A combination of the reaction tube 11 and the manifold 5 constitutes a reaction container 1 in this embodiment.

Around the reaction tube 11 is installed a heating part 12 made of a resistive heating material so as to surround the reaction tube 11 over the entire circumference. The heating part 12 is held by a heat insulator (not shown) covering a space around the reaction tube 11 from above.

An opening formed in the lower surface of the manifold 5 is closed with a disc-like lid 56 made of quartz. The lid 56 is installed on a boat elevator 51. By moving the boat elevator 51 upward and downward, it is possible to switch a state in which the lid 56 closes the opening of the manifold 5 and a state in which the lid 56 opens the opening of the manifold 5. A rotary shaft 53 is installed to penetrate through the lid 56 and the boat elevator 51. The rotary shaft 53 extends upward from an upper face of the lid 56. The rotary shaft 53 is configured to rotate around a vertical axis by a driving part 52 installed below the boat elevator 51.

A wafer boat 2 as a substrate holder is installed on an upper end of the rotary shaft 53 at a position surrounded by the peripheral side wall of the reaction tube 11. The wafer boat 2 includes a circular top plate 21 made of quartz having a diameter larger than a diameter (300 mm) of the wafer W, and a ring-shaped bottom plate 22. The top plate 21 and the bottom plate 22 are disposed so as to face each other vertically and are connected to each other by a plurality of pillars 23 arranged at equal intervals over a semi-circumferential area of a peripheral portion of each of the top plate 21 and the bottom plate 22. Between the top plate 21 and the bottom plate 22 is installed a plurality of mounting stands (not shown) on which wafers W are mounted one by one, in a shelf shape with a space formed therebetween in the vertical direction.

Further, an insulation unit 50 is installed between the lid 56 and the wafer boat 2. The insulation unit 50 includes a plurality of annular insulation fins 54 made of, for example, quartz. The plurality of annular insulation fins 54 is supported in a shelf shape by a plurality of pillars 55 installed at intervals in the circumferential direction on the upper surface of the lid 56. The rotary shaft 53 described above is inserted inward of the annular insulation fins 54. The insulation unit 50 is disposed so as to surround the side peripheral surface of the rotation shaft 53.

The wafer boat 2 and the insulation unit 50 are moved upward and downward together with the lid 56 by the boat elevator 51 described above and are moved between a process position (a position shown in FIG. 1) at which the wafer boat 2 is located inside the reaction tube 11 and a delivery position at which the wafer boat 2 is unloaded from the reaction container 1 and at which a wafer W is delivered between a delivery mechanism (not shown) and the wafer boat 2.

A gas injector 3 for supplying an HCD gas and gas injectors 4 (an oxygen gas injector 4a and a hydrogen gas injector 4b) for supplying an oxygen gas and a hydrogen gas, respectively, are disposed inside the reaction tube 11 between the wafer boat 2 located at the process position and the peripheral side wall of the reaction tube 11.

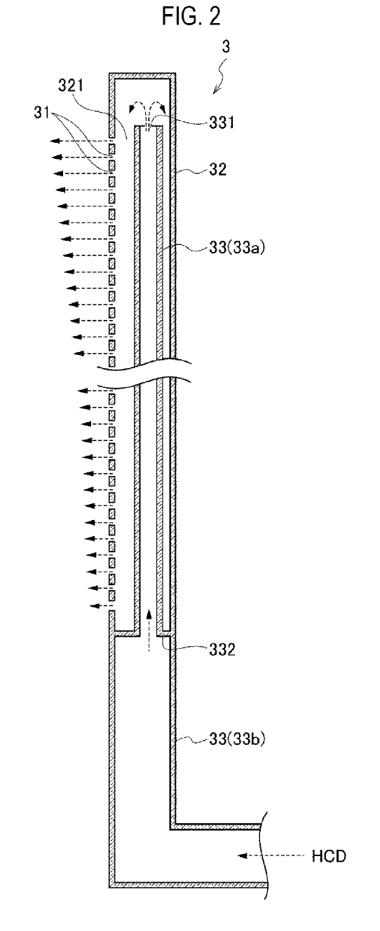

Among these gas injectors 3 and 4, the gas injector 3 for supplying the HCD gas having a configuration according to an embodiment of the present disclosure will be described in detail later with reference to FIG. 2.

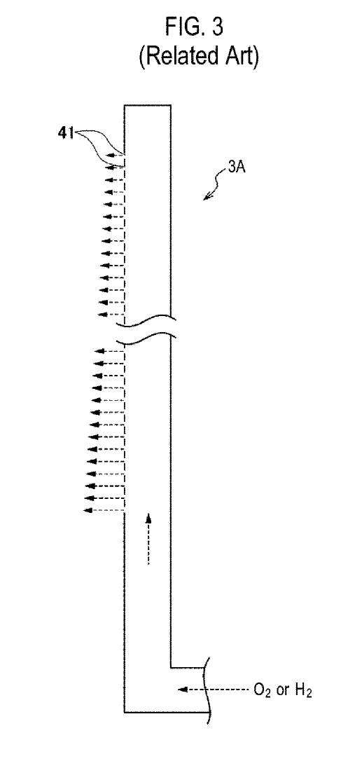

On the other hand, as illustrated in FIGS. 1 and 3, the gas injectors 4 (4a and 4b) for respectively supplying the oxygen gas and the hydrogen gas employ a conventional structure in which a plurality of gas supply holes 41 is longitudinally formed at intervals in the lateral surface of an elongated tubular quartz tube whose end is closed. The gas injectors 4 are disposed inside the reaction tube 11 so as to extend vertically with surfaces in which the gas supply holes 41 are formed facing the side of the wafer boat 2. In a state in which the gas injectors 4 are disposed inside the reaction tube 11, the plurality of gas supply holes 41 is formed substantially at equal intervals over a range from the lowermost position at which the lowermost wafer W is mounted to the uppermost position at which the uppermost wafer W is positioned inside the wafer boat 2.

For the sake of convenience of illustration, in FIG. 1, the gas injectors 4a and 4b are shown to be disposed at radially displaced positions when viewing the cross section of the reaction tube 11. In practice, however, the gas injectors 4a and 4b may be disposed side by side along the inner wall surface of the reaction tube 11 when viewed from the wafer boat 2 side.

A lower end side (proximal end side) of each of the gas injectors 3 and 4 extends up to the side of the manifold 5, is bent toward the peripheral side wall of the manifold 5 and is connected to a respective pipeline constituting supply lines of the HCD gas, the oxygen gas and the hydrogen gas. Openings formed to be connected to the respective pipelines in the gas injectors 3 and 4 correspond to gas inlets.

The gas supply lines penetrate through the manifold 5 and are connected to an HCD gas supply source 71, an oxygen gas supply source 72 and a hydrogen gas supply source 73 via on-off valves V11, V12 and V13, and flow rate regulators M11, M12 and M13, respectively. A combination of the HCD gas supply source 71, the on-off valve V11, the flow rate regulator M11 and the gas supply line for the HCD gas corresponds to a film-forming gas supply part of this embodiment.

In addition, in order to discharge the HCD gas, the oxygen gas and the hydrogen gas from the interior of the reaction tube 11, a purge gas supply source (not shown) for supplying an inert gas such as a nitrogen gas as a purge gas may be installed in the gas supply lines.

Further, an exhaust pipe 61 is connected to the manifold 5. A vacuum exhaust part 63 is connected to the downstream side of the exhaust pipe 61 via a pressure regulator (for example, a butterfly valve) 62 for regulating an exhaust flow rate. Since the exhaust pipe 61 is connected to the manifold 5, a film forming gas (the HCD gas, the oxygen gas and the hydrogen gas) supplied from the gas injectors 3 and 4 into the reaction tube 11 flows downward inside the reaction tube 11 and subsequently, is exhausted to the outside. A combination of the exhaust pipe 61, the pressure regulator 62 and the vacuum exhaust part 63 corresponds to an exhaust part of this embodiment.

Furthermore, the vertical heat treatment apparatus includes a control part 8. The control part 8 is implemented with a computer including, for example, a CPU (Central Processing Unit) (not shown) and a storage part (not shown). The storage part stores a program incorporating a group of steps (instructions) so as to control a film forming process (heat treatment) performed by the vertical heat treatment apparatus, which includes moving the wafer boat 2 with target wafers W held therein to the process position, loading the wafer boat 2 into the reaction tube 11, and supplying a precursor gas and a reaction gas in a predetermined order and at predetermined flow rates in a switching manner This program is stored in a storage medium such as a hard disk, a compact disk, a magneto-optical disk, a memory card, and the like, and is installed on the computer from the storage medium.

In the vertical heat treatment apparatus configured as above, the gas injector 3 for supplying the HCD gas is disposed inside the reaction tube 11 so as to extend in the vertical direction, and has a specific configuration suitable for the vertical heat treatment apparatus.

Hereinafter, the specific configuration of the gas injector 3 will be described with reference to FIG. 2.

Prior to describing the configuration of the gas injector 3 in detail, problems caused when an HCD gas is supplied using a conventional gas injector 3A illustrated in FIG. 3 will be described.

A pressure of a gas flowing through the gas injector 3A having an elongated tubular shape is higher at the upstream side (the distal end side of the gas injector 3A) than at the downstream side (the proximal end side of the gas injector 3A) in the flow direction. This results in a flow rate distribution in which a gas supplied from each gas supply hole 41 has a high flow rate at the proximal end side and gradually decreases toward the distal end side.

In various gas injectors 3, 3A, 3a to 3e, 4 (4a and 4b) and 4c illustrated in FIGS. 2 to 8B, lengths of arrows indicating a flow of gas are shown to be varied depending on a flow rate of gas supplied from the gas supply holes 31 and 41. In these figures, a longer arrow of broken line indicates a higher flow rate of gas, but the length of each arrow does not indicate the flow rate of gas strictly.

When the gas injector 4 having the flow rate distribution described above is used to supply the HCD gas, the HCD gas is supplied to wafers W held at the lower side of the wafer boat 2 at a higher concentration than wafers W held at the upper side of the wafer boat 2. This results in a distribution in which HCD is absorbed onto the wafers W held at the lower side more than the wafers W held at the upper side, so that HCD is adsorbed at different adsorption amounts in an inter-plane of the wafers W.

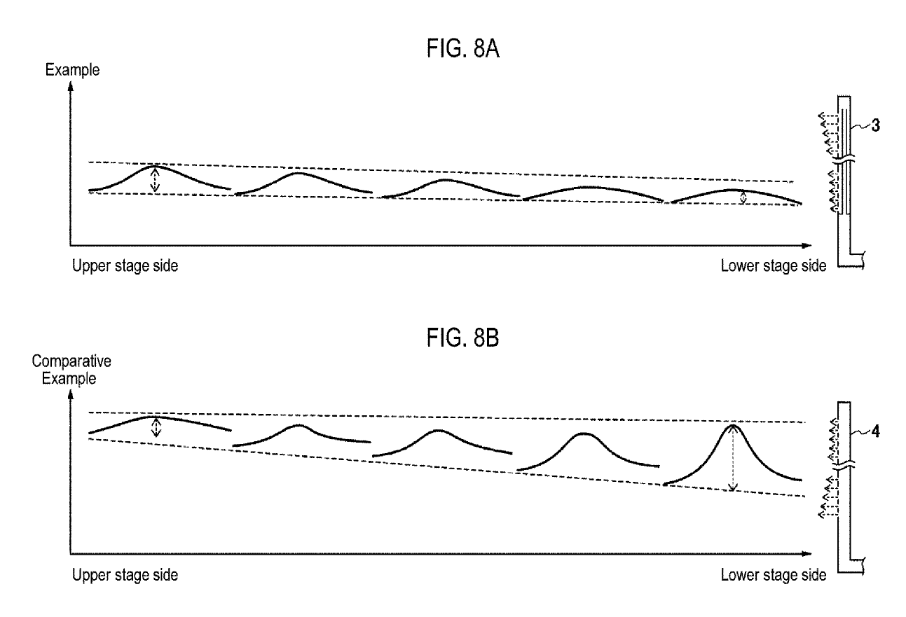

As such, even in respective films of SiO₂ obtained by reacting the HCD adsorbed onto the surfaces of the wafers W with O radicals and OH radicals, wafer inter-plane film thicknesses are different from each other. As a result, the SiO₂ films having different thicknesses are laminated so that SiO₂ films having different inter-plane film thickness distributions are formed (see Comparative Example shown in FIG. 8B to be described later).

Particularly, in a vertical heat treatment apparatus configured to exhaust the film forming gas existing in the reaction tube 11 toward the lower side of the vertical heat treatment apparatus, the HCD gas of a relatively high concentration supplied into the lower region of the wafer boat 2 is exhausted away before it diffuses sufficiently toward an internal upper space of the reaction tube 11. Therefore, there is a possibility that the variation in inter-plane film thickness distribution of the wafer W becomes more remarkable.

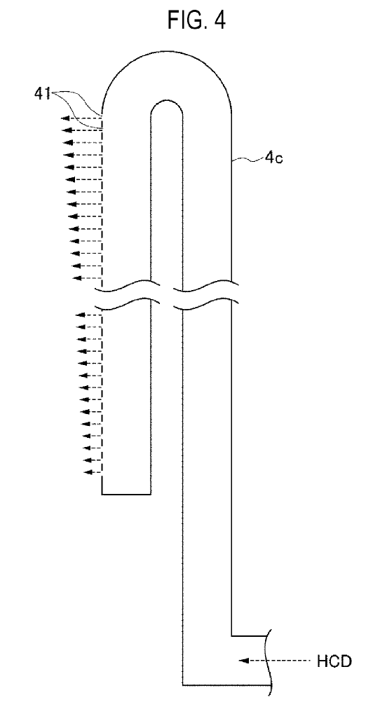

In order to solve the above problems, as illustrated in FIG. 4, a method using a U-shaped folded gas injector 4c a may be used. The gas injector 4c can supply an HCD gas of higher concentration into the internal upper space of the reaction tube 11. At this time, when the HCD gas inside the reaction tube 11 is exhausted downward, the high concentration of HCD gas supplied into the internal upper space is exhausted while diffusing into an internal lower space of the reaction tube 11. Thus, the high concentration of HCD gas may be also supplied onto the wafers W held at the lower side of the wafer boat 2, possibly improving a variation in the wafer inter-plane film thickness distribution.

However, since the U-shaped folded gas injector 4c tends to be increased in size, it may be sometimes difficult to dispose the gas injector 4c inside the reaction tube 11. Further, due to a thermal decomposition or the like, a Si film or the like is likely to be formed on an inner wall surface of the folded portion of the gas injector 4c, at which a pressure of the HCD gas is relatively high and the flow direction of the HCD gas changes. If such a Si film is peeled off from the inner wall surface of the gas injector 4c, particles of the Si film may be introduced into the reaction tube 11, which may become a contamination source of the wafers W.

FIG. 2 illustrates the gas injector 3 according to an embodiment of the present disclosure. Similar to the conventional gas injector 3A described with reference to FIG. 3, the gas injector 3 of this embodiment has an elongated cylindrical quartz tube (for example, having the same pipe diameter as the conventional gas injector 3A) whose end is terminated and whose lateral surface has the plurality of gas supply holes 31 formed at intervals. Hereinafter, in the gas injector 3, an upper region where the gas supply holes 31 are formed is referred to as an injector main body 32. The gas injector 3 of this embodiment has a structure in which a gas introduction pipe 33 made of quartz having a pipe diameter smaller than that of the injector main body 32 is inserted into the injector main body 32.

A gas introduction port 331 is formed in an upper end surface of the gas introduction pipe 33 so that an internal space of the gas introduction pipe 33 communicates with an internal space 321 of the injector main body 32. On the other hand, at the lower end portion of the gas introduction pipe 33, a gap between the peripheral side wall of the injector main body 32 and the outer circumferential surface of the gas introduction pipe 33 is blocked by an annular partition member 332 and the lower end surface of the gas introduction pipe 33 is opened.

In this configuration, a portion below the partition member 332 in the gas injector 3 (the upstream side as viewed in the flow direction of the HCD gas) may refer to a pipe portion 33b of the proximal end side of the gas introduction pipe 33. On the other hand, a region of the gas introduction pipe 33 inserted into the injector main body 32 constitutes a smaller-diameter pipe portion 33a of the gas introduction pipe 33.

In this fashion, the injector main body 32 and the gas introduction pipe 33 are formed as a unit along the vertical direction with the partition member 332 formed between the injector main body 32 and the gas introduction pipe 33, thus constituting the gas injector 3. In the interior of the gas injector 3, a flow path through which the HCD gas supplied from the HCD gas supply source 71 is introduced into the internal space 321 of the injector main body 32 through the gas introduction pipe 33 may be formed.

Further, in the internal space 321, the gas introduction pipe 33 is disposed at a position at which the central axis of the gas introduction pipe 33 is shifted in a direction away from the formation surface of the gas supply holes 31 with respect to the central axis of the injector main body 32. As a result, a gap between an inner circumferential surface of the injector main body 32 and an outer circumferential surface of the gas introduction pipe 33 in a direction in which the gas supply holes 31 are formed, is enlarged so that the HCD gas introduced into the internal space 321 can easily reach the gas supply holes 31.

Hereinafter, the operation of the vertical heat treatment apparatus including the above-described gas injector 3 will be described. First, the wafer boat 2 is lowered to the delivery position and the wafers W are mounted on all the mounting stands of the wafer boats 2 by an external substrate transfer mechanism (not shown). If the wafers W are loaded into the reaction tube 11, the heating part 12 starts to heat the wafers W so that each wafer W reaches a preset temperature.

Thereafter, the boat elevator 52 is raised to locate the wafer boat 2 at the process position inside the reaction container 1 and the opening of the manifold 5 is hermetically sealed by the lid 56. Subsequently, evacuation is performed by the vacuum exhaust part 63 so that the internal pressure of the reaction container 1 reaches a preset degree of vacuum, and the wafer boat 2 is rotated by the rotary shaft 53 at a preset rotation speed.

In this manner, once a film formation process using the ALD method is ready to be performed, the HCD gas begins to be supplied at a preset flow rate from the HCD gas supply source 71. As indicated by a broken line in FIG. 2, the HCD gas supplied from the supply line to the proximal end (the gas inlet) of the gas injector 3 flows upward and subsequently is introduced into the gas introduction pipe 33 having a smaller pipe diameter. Subsequently, the HCD gas that passed through the gas introduction pipe 33 is introduced into and diffused in the internal space 321 of the injector main body 32 through the gas introduction port 331. Thereafter, the HCD gas is supplied into the reaction tube 11 through the gas supply holes 31.

Here, as illustrated in FIG. 2, the gas introduction port 331 in the gas injector 3 of this embodiment is opened at a position higher than the uppermost gas supply hole 31. Thus, the HCD gas introduced from the gas introduction port 331 and diffused in the internal space 321 has a higher pressure at the distal end side of the gas injector 3 and a lower pressure at the proximal end side thereof. As a result, similarly to the gas injector 4c illustrated in FIG. 4, the HCD gas of higher concentration can be supplied into the internal upper space of the reaction tube 11 and the HCD gas of lower concentration can be supplied into the internal lower space thereof.

In addition, since the pipe diameter of the gas introduction pipe 33 (the smaller-diameter pipe portion 33a) is smaller than the diameter of the injector main body 32, the gas introduction pipe 33 constitutes a throttle portion having a narrow passage so that the pressure of the HCD gas when the HCD gas flows through the gas introduction pipe 33 is lowered. Further, the gas introduction port 331 is opened toward the closed end surface of the injector main body 32. Thus, the HCD gas after being immediately introduced into the internal space 321 is greatly changed in orientation and diffused inward of the internal space 321. The pressure of the HCD gas is further decreased in the orientation change in the flow of the HCD gas. From this point of view, it can be said that the internal space 321 of the injector main body 32 plays a role of a buffer space for alleviating the flow momentum of the HCD gas.

When the HCD gas whose flow momentum is alleviated is diffused in the internal space 321, the influence of diffusion increases. This reduces a difference between the pressure of the HCD gas at the distal end side of the gas injector 3, which is close to the gas introduction port 331, and the pressure of the HCD gas at the proximal end side of the gas injector 3, which is far from the gas introduction port 331. As a result, in comparison with the conventional gas injector 3A illustrated in FIG. 3, it is possible to more uniformly supply the HCD gas from the plurality of gas supply holes 31 formed along the vertical direction in the injector main body 32.

As described above, similarly to the U-shaped folded gas injector 4c illustrated in FIG. 4, the gas injector 3 of this embodiment can supply the HCD gas of higher concentration to the internal upper space of the reaction tube 11 rather than the internal lower space thereof. In addition, since the internal space 321 of the injector main body 32 plays a role of a buffer space, the gas injector 3 can more uniformly supply the HCD gas from the gas supply holes 31, compared with the U-shaped folded gas injector 4c.

Further, in the gas injector 3 of this embodiment, the pressure of the HCD gas in the internal space 321 is lowered so that the intermolecular distance of HCD is increased. This makes it difficult for thermal decomposition of the HCD gas to occur, thereby preventing an Si film from being formed inside the injector main body 32 and suppressing particles from being produced.

The HCD gas supplied from the gas supply holes 31 of the gas injector 3 is diffused into the reaction tube 11, reaches the wafers W held by the wafer boat 2 that rotates around the rotary shaft 53, and is adsorbed onto the surfaces of the wafers W. At this time, since the interior of the reaction tube 11 (the reaction container 1) is being exhausted downward, an HCD gas having relatively high concentration existing at the internal upper space is exhausted while being diffused into the internal lower space. As a result, the HCD gas flowing from the upper side of the reaction tube 11 can be also supplied onto the wafers W held at the lower side of the reaction tube 11 so that the HCD gas can be uniformly adsorbed onto the wafers W along the height direction of the wafer boat 2.

In this way, after the time required for adsorbing a predetermined amount of HCD gas onto each wafer W elapses, the supply of the HCD gas from the HCD gas supply source 71 is stopped. At this time, a purge gas is supplied as necessary to discharge the HCD gas remaining in the reaction tube 11.

Thereafter, an oxygen gas and a hydrogen gas are supplied at a preset flow rate into the reaction tube 11 from the oxygen gas supply source 72 and the hydrogen gas supply source 73, respectively. Active species including O radicals and OH radicals are produced from the oxygen gas and the hydrogen gas supplied into the reaction tube 11 in a low pressure and high temperature atmosphere. These O radicals and OH radicals react with HCD adsorbed onto the wafers W, thereby forming an SiO2 film.

In the above reaction, for example, in a case where a distribution of concentrations of O radicals and OH radicals supplied onto the wafers W held in the stages of the wafer boat 2 exerts a small influence on variations in the inter-plane film thickness distribution of the wafers W, the conventional gas injector 3A having a single tube structure shown in FIG. 3 may be used to supply O radicals and OH radicals. In other words, when HCD is uniformly adsorbed on the inter-plane of the wafer W, even when the concentrations of O radicals and OH radicals supplied to the wafers W are different from each other, the conventional gas injector 3A having a single tube structure may be employed as long as it is possible to supply O radicals and OH radicals at a sufficient amount to react with HCD and form an SiO₂ film having a uniform inter-plane film thickness distribution.

In this regard, in a case where the distribution of flow rates of the oxygen gas or the hydrogen gas from the gas supply holes 41 of the oxygen gas injector 4a and the hydrogen gas injector 4b exerts a large influence on a variation in the inter-plane film thickness distribution of the wafer W, the gas injector 3 having the buffer space illustrated in FIG. 2 may be used to supply an oxygen gas or a hydrogen gas (reaction gas). In this case, a combination of the oxygen gas supply source 72, the hydrogen gas supply source 73, the on-off valves V12 and V13, the flow rate regulators M12 and M13 and the oxygen gas and hydrogen gas supply lines corresponds to the film-forming gas supply part of this embodiment.

Then, after a predetermined time required for reacting the HCD gas adsorbed onto each wafer W elapses, the supply of the oxygen gas and the hydrogen gas from the oxygen gas supply source 72 and the hydrogen gas supply source 73 is stopped. If necessary, a purge gas is supplied to discharge the oxygen gas and the hydrogen gas remaining in the reaction tube 11. Thereafter, the supply of the HCD gas from the HCD gas supply source 71 is resumed to adsorb HCD onto the wafers W.

Thus, a cycle including the supply of the HCD gas and the supply of the oxygen gas and the hydrogen gas is repeatedly performed. If the cycle is performed a predetermined number of times, the interior of the reaction tube 11 is purged after stopping the supply of the oxygen gas and the hydrogen gas in the final cycle. Then, after returning the internal pressure of the reaction container 1 to atmospheric pressure, the wafer boat 2 is lowered to unload the wafers W subjected to the film forming process. In this way, a series of operations is ended.

The vertical heat treatment apparatus according to this embodiment has the following effects. The gas injector 3 is disposed inside the reaction container 1 so as to extend in the vertical direction, the gas introduction pipe 33 is installed integrally with the injector main body 32 constituting the gas injector 3 in the internal space 321 of the injector main body 32, and the HCD gas is introduced into the internal space 321 through the gas introduction pipe 33. As a result, while limiting an increase in the size of the gas injector 3, it is possible to (1) form a flow rate distribution in which the flow rate of the HCD gas (film forming gas including a precursor gas and a reaction gas) supplied from the gas supply holes 31 formed at the proximal end side of the gas injector 3 is lower than the flow rate of the HCD gas supplied from the gas supply holes 31 formed at the distal end side thereof, and (2) make a difference between the supply flow rate of the HCD gas at the distal end side and the supply flow rate of the HCD gas at the proximal end side as small as possible.

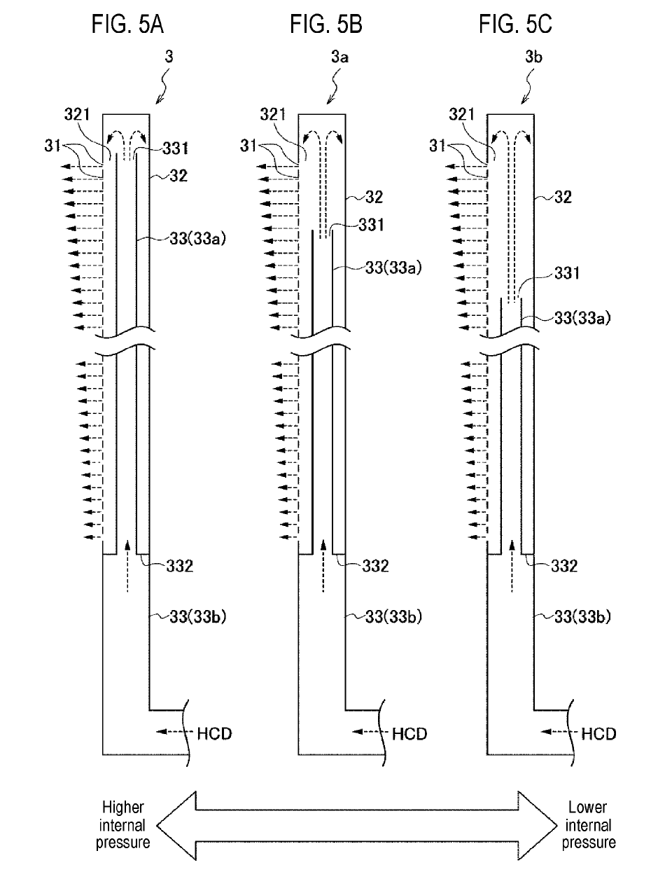

Here, in the gas injector 3 in which the gas introduction pipe 33 is inserted into the injector main body 32, when the flow rate of the film forming gas supplied from the HCD gas supply source 71 is constant, an internal average pressure of the internal space 321 increases as the volume of the internal space 321 decreases. Further, the average pressure (hereinafter also referred to as an “internal pressure” in the description of FIGS. 5A to 5C) can be decreased by increasing the volume of the internal space 321.

As illustrated in FIGS. 5A to 5C, by changing the length of the gas introduction pipe 33 inserted into the injector main body 32, it is possible to change the volume of the internal space 321 and change the internal pressure of the internal space 321. In the embodiment shown in FIGS. 5A to 5C, the internal pressure of the internal space 321 is the highest in the gas injector 3 having the longest length of the gas introduction pipe 33 inserted into the injector main body 32 (FIG. 5A) and is the lowest in a gas injector 3b having the shortest length of the gas introduction pipe 33 (FIG. 5C).

In the vertical heat treatment apparatus, one of the gas injectors 3, 3a and 3b illustrated in FIGS. 5A to 5C may be appropriately selected depending on the distribution of supply flow rate of a film forming gas required for the reaction tube 11, internal pressure conditions that makes it difficult for an Si film to be formed in the injector main body 32, and the like.

Here, like the gas injectors 3a and 3b illustrated in FIGS. 5B and 5C,when the gas introduction pipe 33 is shortened, the opening of the gas introduction port 331 is located below the gas supply hole 31 formed at the uppermost side. Even in this case, if the gas introduction port 331 is formed in the upper end surface of the gas introduction pipe 33, the film forming gas introduced into the internal space 321 flows upward through the injector main body 32 along the introduction direction of the gas introduction pipe 33 and reaches the upper end surface of the injector main body 32, thereby forming a gas flow whose direction is changed. As a result, by supplying the film forming gas with a relatively high pressure to a region at the side of the gas supply holes 31 disposed above the gas introduction port 331, it is possible to form a flow rate distribution in which the supply flow rate of the film forming gas from the gas supply holes 31 formed at the distal end side of the injector main body 32 is relatively large.

As described above, in the case where a method of changing the volume of the internal space 321 according to the length of the gas introduction pipe 33 is employed, the gas introduction port 331 formed in the distal end of the gas introduction pipe 33 is positioned to be higher than the lowermost gas supply hole 31 among the plurality of gas supply holes 31 formed in the injector main body 32. More specifically, the length of the gas introduction pipe 33 may be determined so that the gas introduction port 331 is positioned above the height position which is half the formation range of the gas supply holes 31.

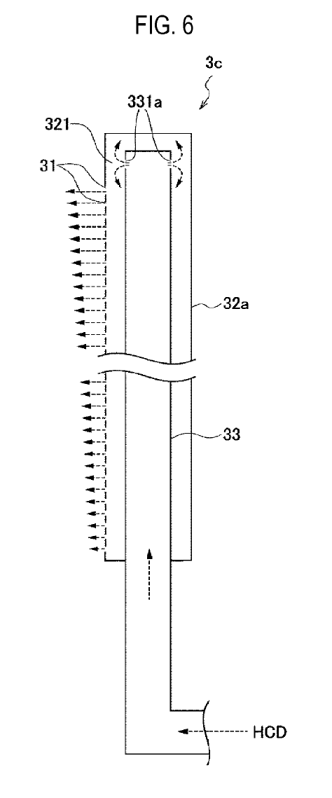

The configuration in which the injector main body 32 and the gas introduction pipe 33 are integrated is not limited to the case where the gas introduction pipe 33 having a small pipe diameter is inserted into the injector main body 32. As an example, as illustrated in FIG. 6, in a gas introduction pipe 33 having a straight pipe shape whose pipe diameter from the proximal end side to the distal end side is not changed, an upper region of the gas introduction pipe 33 may be covered with the injector main body 32 having a relatively large pipe diameter.

In addition, the gas introduction pipe 33 illustrated in FIG. 6 shows an example in which a gas introduction port 331a having an opening size smaller than the pipe diameter of the gas introduction pipe 33 is formed in the lateral surface of the gas introduction pipe 33. In this example, instead of the smaller-diameter pipe portion 33a, the gas introduction port 331a functions as a throttle portion which lowers a pressure at the time of introducing the film forming gas into the internal space 321.

Furthermore, in the case where the gas introduction port 331a is formed in the lateral surface of the gas introduction pipe 33, it is necessary to prevent the film forming gas from being discharged from the gas introduction port 331a toward the gas supply holes 31. To do this, as illustrated in FIG. 6, the gas introduction port 331a may be formed to be higher than the uppermost gas supply hole 31 or may be formed to face a position different from the formation surface of the gas supply holes 31 so that the film forming gas is oriented toward the respective position.

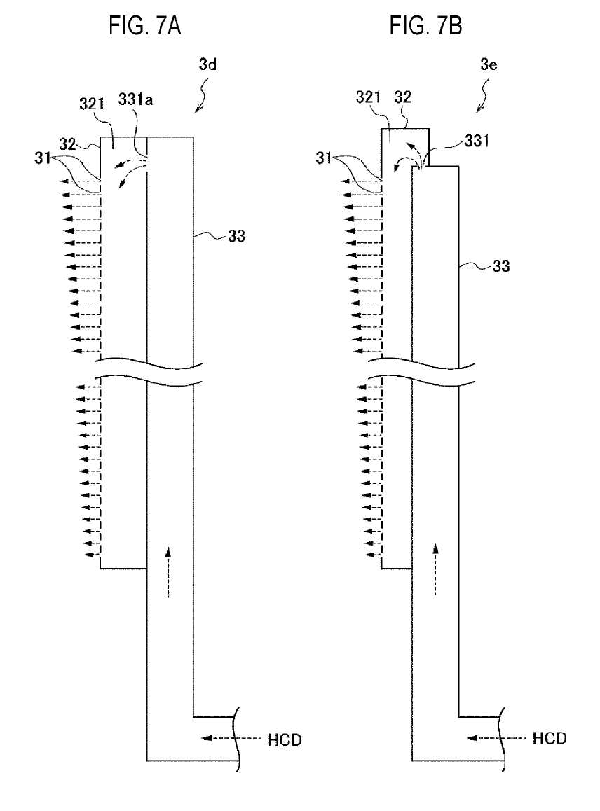

Further, the configuration in which the injector main body 32 and the gas introduction pipe 33 are integrated is not limited to the case where the gas introduction pipe 33 is inserted into the injector main body 32. As an example, like gas injectors 3d and 3e illustrated in FIGS. 7A and 7B, the injector main body 32 and the gas introduction pipe 33 may be arranged side by side while being integrated.

The gas injector 3d of FIG. 7A shows an example in which lateral wall surfaces of the injector main body 32 and the gas introduction pipe 33 are connected to each other and a gas introduction port 331a as a throttle portion is formed at an upper side of the connection portion.

In addition, the gas injector 3e of FIG. 7B shows an example in which a notch into which a portion of a lateral surface and a portion of an upper surface of the gas introduction pipe 33 is inserted is formed in the injector main body 32, and the gas introduction pipe 33 is inserted into the notch so as to cover the portions of the lateral surface and upper surface of the gas introduction pipe 33. Further, in this example, the gas introduction port 331 as a throttle portion is formed in the upper surface of the gas introduction pipe 33 covered with the injector main body 32.

Even in these examples, since the injector main body 32 and the gas introduction pipe 33 are integrated, it is possible to make the gas injectors 3d and 3e compacter than the U-shaped folded gas injector 4c illustrated in FIG. 4.

Furthermore, the type of film forming gas used and the type of film formed in the vertical heat treatment apparatus including the gas injectors 3 and 3a to 3e of this embodiment are not limited to the above-described examples (the formation of an SiO₂ film (metal oxide film) using the HCD gas as a precursor gas, and the oxygen gas and the hydrogen gas as a reaction gas).

For example, it may be possible to use an ALD method to form a metal nitride film by reaction of a precursor gas containing a metal precursor with a reaction gas containing nitrogen, to form a metal film by reaction of a precursor gas containing a metal precursor with a gas that decomposes and reduces the precursor, etc.

### EXAMPLES

### [Experiments]

A vertical heat treatment apparatus of the same downward exhaust type as that shown in FIG. 1 was used to form an SiO₂ film on each wafer W held by the wafer boat 2 using the ALD method and a film thickness distribution of each wafer W was measured.

### A. Experimental Conditions

### Example

An SiO₂ film was formed using an ALD method by supplying an HCD gas using the gas injector 3 according to the embodiment shown in FIG. 2 while supplying an oxygen gas and a hydrogen gas using the conventional gas injector 3A shown in FIG. 3. The HCD gas was supplied at a flow rate of 200 sccm for 6 seconds from the HCD gas supply source 71, and the oxygen gas and the hydrogen gas were supplied at flow rates of 3,000 sccm and 1,000 sccm for 10 seconds from the oxygen gas supply source 72 and the hydrogen gas supply source 73, respectively. A cycle including supplying these gases was performed 100 times to form a film. The internal pressure of the reaction container 1 was 40 Pa, the heating temperature of the wafers W by the heating part 12 was 600 degrees C., and the rotational speed of the wafer boat 2 around the rotary shaft 53 was 2.0 rpm. Film thickness distributions of five wafers W mounted on the 20th, 60th, 90th, 130th and 160th stages from the lowermost stage of the wafer boat 2 which holds the wafers were measured with a film thickness gauge.

### Comparative Example

Film formation and film thickness distribution measurement were carried out under the same conditions as in the Example except that an HCD gas was supplied using the conventional gas injector 3A shown in FIG. 3.

### B. Experimental Results

The results of the Example and Comparative Examples are shown in FIGS. 8A and 8B, respectively. Solid lines shown in each of FIGS. 8A and 8B indicate a schematic film thickness distribution of the SiO₂ film when viewed from a cross section passing through the center of each wafer W. In each figure, measurement results of the film thickness distributions are arranged in such a manner that the film thickness distribution of the lowermost wafer W among the wafers W on which the film thickness measurement was performed is depicted at the right end, and the film thickness distributions of the wafers W positioned at the upper stage side are sequentially depicted at the left side.

The result of the Example shown in FIG. 8A shows an upwardly convex film thickness distribution in which the film thickness of the SiO₂ film formed at any mounting position is larger at the central side of the wafer W and is smaller at the peripheral side thereof. Further, specifically describing the center positions of the wafers W having the largest film thickness, the change in the film thickness of each wafer W was measured. As a result, it was confirmed that wafers W held at the upper stage side of the wafer boat 2 have a thicker SiO2 film than those held at the lower stage side thereof. This change in the film thickness corresponds to a distribution of the flow rate of the HCD gas discharged from the gas injector 3. On the other hand, a variation in the maximum value of the film thickness between the five wafers W on which the film thickness distribution was measured falls within a range not more than twice at a maximum.

In contrast, the result of the Comparative Example shown in FIG. 8B shows an upwardly convex film thickness distribution in which the film thickness of the SiO₂ film for all the wafers W is larger at the central side of the wafer W and is smaller at the peripheral side thereof. It was confirmed that the film thickness (the maximum value of the film thickness at the central position of the wafer W) of the SiO₂ film of each wafer W held at the lower stage side of the wafer boat 2 is larger than the film thickness of the SiO₂ film of each wafer W held at the upper stage side thereof. This change in the film thickness corresponds to a distribution of the flow rate of the HCD gas discharged from the conventional gas injector 3A. Furthermore, a variation in the maximum value of the film thickness between the five wafers W on which the film thickness distribution was measured is increased more than twice. It can be evaluated based on the above experimental results that the supply of the HCD gas using the gas injector 3 according to the embodiment can provide a more uniform inter-plane film thickness distribution of films formed on the wafers W held by the wafer boat 2 than the case where the conventional gas injector 3A is used.

According to the present disclosure in some embodiments, a film forming gas is introduced into an internal space of an injector main body disposed to vertically extend inside a reaction container via a gas introduction pipe integrated with the injector main body. It is therefore possible to supply a film forming gas suitable for a vertical heat treatment apparatus while limiting an increase in size of a gas injector.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gas injector installed in a vertical heat treatment apparatus which performs a heat treatment on a plurality of substrates held by a substrate holder which holds the plurality of substrates vertically arranged in a shelf shape and is loaded into a vertical reaction container around which a heating part is disposed, the gas injector being configured to supply a film forming gas for film formation to the plurality of substrates into the vertical reaction container, comprising:
a tubular injector main body disposed inside the vertical reaction container so as to extend in a vertical direction and has a plurality of gas supply holes formed therein along the vertical direction; and
a tubular gas introduction pipe installed to be integrated with the tubular injector main body in the vertical direction and includes a gas inlet to which the film forming gas is inputted and a gas introduction port which communicates with an internal space of the tubular injector main body and through which the film forming gas is introduced into the internal space.

2. The gas injector of claim 1, wherein the gas introduction pipe is inserted into the internal space such that the tubular injector main body is integrated with the gas introduction pipe.

3. The gas injector of claim 2, wherein the gas introduction port is opened at an upper end surface of the gas introduction pipe inserted into the internal space.

4. The gas injector of claim 1, wherein the gas introduction port is formed to be higher than the lowermost gas supply hole among the plurality of gas supply holes.

5. The gas injector of claim 1, further comprising: a throttle portion formed in the gas introduction pipe to narrow a flow path through which the film forming gas flows so that a pressure of the film forming gas introduced into the internal space is lower than a pressure of the film forming gas introduced into the gas introduction pipe.

6. A vertical heat treatment apparatus comprising the gas injector of claim 1.

7. The vertical heat treatment apparatus of claim 6, further comprising: an exhaust part installed in the vertical reaction container at a position at which the film forming gas supplied from the tubular gas injector into the vertical reaction container flows downward and subsequently is exhausted outward of the vertical reaction container.

8. The vertical heat treatment apparatus of claim 6, further comprising a film-forming gas supply part configured to supply the film forming gas toward the gas inlet of the gas introduction pipe,
wherein the film forming gas contains a component which is thermally decomposed to form a film on an inner surface of the tubular injector main body or the gas introduction pipe.
